(19) United States
(12) Patent Application Publication
(10) Pub. No.: US 2020/0259481 A1
(43) Pub. Date: Aug. 13, 2020

(54) FILTER DEVICE AND COMMUNICATION APPARATUS

(71) Applicant: KYOCERA Corporation, Kyoto-shi, Kyoto (JP)

(72) Inventor: Toshiya KIMURA, Kyotanabe-shi, Kyoto (JP)

(21) Appl. No.: 16/642,594

(22) PCT Filed: Aug. 23, 2018
(86) PCT No.: PCT/JP2018/031194

§ 371 Date: Feb. 27, 2020

(30) Foreign Application Priority Data
Aug. 29, 2017 (JP) 2017-164302
Sep. 4, 2017 (JP) 2017-169814

(51) Int. Cl. H03H 9/72; H03H 7/38

(52) U.S. Cl. CPC H03H 9/72; H03H 2007/386; H03H 7/383

(57) ABSTRACT

An antenna terminal is connected to a first filter and second filter, which are branched from each other when viewed from the antenna terminal, and are different in passing bands from each other. An individual inductor is connected in series to a branch point from which the first filter is branched to be independent from other filters when viewed from the antenna terminal. And a common inductor is located between a position between the antenna terminal and the branch point and a reference potential and is commonly connected in parallel with respect to the filters. The first filter is higher in frequency of passing band compared with the other filters. A susceptance when viewing the second filter side from the antenna terminal is larger than a susceptance when viewing the first filter side from the antenna terminal at frequencies of passing bands of them.

### TECHNICAL FIELD

The present disclosure relates to a filter device and a communication apparatus having a function of filtering an electrical signal.

### BACKGROUND ART

Known in the art is a filter device having a plurality of filters which have passing bands different from each other and which are all connected to a common terminal (for example Japanese Patent Publication No. 04-16014). Patent Literature 1 describes a duplexer having a transmission filter and a reception filter which are connected to an antenna terminal wherein a matching circuit is connected to the antenna terminal side of the transmission filter (or reception filter). This matching circuit includes a capacitor which is arranged in series between the antenna terminal and the transmission filter and includes an inductor which is connected in parallel between the matching circuit and a ground potential.

### SUMMARY OF INVENTION

In the filter device as explained above, desirably there are provided a filter device and a communication apparatus adjusting an impedance among the filters.

A filter device according to one aspect of the present disclosure includes an antenna terminal, two or more filters, an individual inductor, and a common inductor. The two or more filters are connected to the antenna terminal, are branched from each other when viewed from the antenna terminal, and are different in passing bands from each other. The two or more filters include a first filter and a second filter. The individual inductor is connected in series between the first filter and a branch point at which the first filter is branched to be independent from the other filter among the two or more filters when viewed from the antenna terminal. The common inductor is located between a position between the antenna terminal and the branch point and a reference potential and is commonly connected in parallel with respect to the two or more filters. Further, the first filter is higher in frequency of passing band compared with the other filter among the two or more filters. The second filter is included. A susceptance when viewing the second filter from the antenna terminal side at a frequency of the passing band of the second filter is larger than a susceptance when viewing the first filter from the antenna terminal side at a frequency of the passing band of the first filter.

A communication apparatus according to one aspect of the present disclosure includes an antenna, a filter device described above with the antenna terminal connected to the antenna, and an IC connected to the filter device.

According to the above configuration, it is possible to suitably adjust the impedance.

### BRIEF DESCRIPTION OF DRAWINGS

FIG. 1 is a schematic view showing the configuration of a communication apparatus according to an embodiment.

FIG. 2 is a schematic view showing the configuration of principal parts of a filter device in the communication apparatus in FIG. 1.

FIG. 3 is a schematic plan view showing the configuration of principal parts in a resonator in the filter device in FIG. 2.

FIG. 4 is a graph showing passing bands and impedances in the filter device in FIG. 2.

FIG. 5A is a Smith chart of impedances when viewed from the antenna terminal side at the passing band frequencies of the filters, and FIG. 5B is a Smith chart showing the impedances when viewed from the antenna terminal side at the passing band frequencies of the filters on a plane of reflection coefficient.

FIG. 6A is a Smith chart of impedances when viewed from the antenna terminal side of the filter device, FIG. 6B is a graph showing a transmission characteristic of a first filter at a passing band B1, FIG. 6C is a graph showing an isolation characteristic between the first filter and a third filter, and

FIG. 6C is an enlarged view of the principal parts in FIG. 6C.

FIG. 7 is an enlarged cross-sectional view of principal parts showing a modification of the filter device.

FIG. 8 is a schematic view showing a modification of the filter device shown in FIG. 2.

FIG. 9 is a schematic cross-sectional view showing the configuration of the filter device in FIG. 8.

FIG. 10 is an explanatory diagram showing the relationships between the configuration of the filter device in FIG. 8 and the circuits.

FIG. 11A to FIG. 11G are disassembled views for explaining conductor patterns of dielectric layers in a structure.

FIG. 12A to FIG. 12F are graphs respectively showing the transmission characteristics and isolations of the filter device.

FIG. 13A to FIG. 13F are graphs respectively showing the transmission characteristics and isolations of the filter device.

FIG. 14A to FIG. 14F are graphs respectively showing the transmission characteristics of a filter device according to a comparative example.

FIG. 15A to FIG. 15F are graphs respectively showing the transmission characteristics of a filter device according to a comparative example.

FIG. 16A to FIG. 16F are graphs respectively showing the transmission characteristic of a filter device according to a comparative example.

FIG. 17A to FIG. 17F are graphs respectively showing the transmission characteristics of a filter device according to a comparative example.

FIG. 18 is a view explaining the configuration of a longitudinally coupled type filter.

FIG. 19A and FIG. 19B are cross-sectional views of principal parts respectively showing a modification of a filter device.

### DESCRIPTION OF EMBODIMENTS

Below, an embodiment will be explained with reference to the drawings. Note that, in the following explanation, the same, similar, or corresponding components will sometimes be given different capital letters of the alphabet such as with the “first filter 19A” and “second filter 19B”. Further, in this case, sometimes the capital letters of the alphabet will be omitted and the components will be simply referred to as the “filters 19” and not differentiated.

(Overall Configuration of Communication Apparatus)

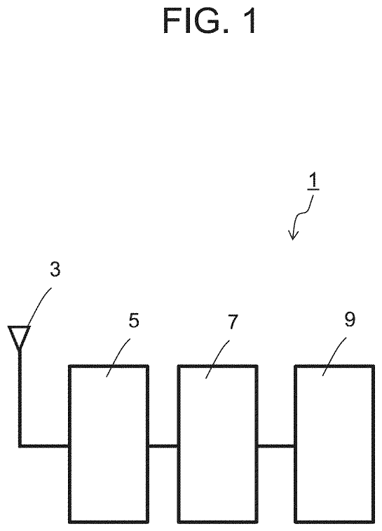

FIG. 1 is a schematic view showing the configuration of principal parts of a communication apparatus 1 according to an embodiment.

The communication apparatus 1 is for example configured as an apparatus which receives or transmits a radio wave and executes predetermined processing. The communication apparatus 1 is for example configured by an antenna 3, a filter device 5, an RF-IC (radio frequency integrated circuit) 7, and a BB-IC (baseband integrated circuit) 9 connected together.

The antenna 3 converts a received wireless signal (radio wave) to an electrical signal. The filter device 5 extracts an electrical signal having a predetermined passing band (plurality of passing bands as will be explained later) from the electrical signal from the antenna 3 and outputs the result. The RF-IC 7 for example demodulates, boosts down in frequency, and digitalizes the electrical signal from the filter device 5. The BB-IC 9 for example performs various processing with respect to the signal from the RF-IC 7.

Further, the signal to be transmitted may be input through the BB-IC 9 and RF-IC 7 to the filter device 5 and only the electrical signal in the predetermined passing band extracted and output to the antenna 3. In this case, the electrical signal from the BB-IC 9 is input to the RF-IC 7, and the electrical signal input toward the filter device 5 is modulated and raised in frequency (converted to high frequency signal of carrier frequency). Further, unwanted components other than the transmission-use passband are stripped in the filter device 5 and the result output toward the antenna 3. The antenna 3 converts the electrical signal to be transmitted to a radio signal.

The communication apparatus 1 may be used for various applications. The carrier frequency (frequency of passing band of filter device 5), the frequency of the baseband, the processing content of the BB-IC 9, and the like may be determined in accordance with the application of the communication apparatus 1. For example, the communication apparatus 1 is used in a mobile phones or GPS (global positioning systems) and other GNSS (global navigation satellite systems). The passing band of the filter device 5, for example, may be set to about 700 MHz to 5 GHz when used in mobile phones. Further, for example, the passing band of the filter device 5 may be set according to the standard of GNSS when used in a GNSS. As one example, it is 1000 MHz to 3000 MHz.

Further, FIG. 1 schematically shows only the principal part. A low pass filter, isolator, amplifier, etc. may be added to suitable positions as well. Further, in the example shown in FIG. 1, an explanation was given taking as an example a case where the RF-IC 7 and the BB-IC 9 were separate members. However, one IC provided with the two functions may be used as well.

(Configuration of Filter Device 5)

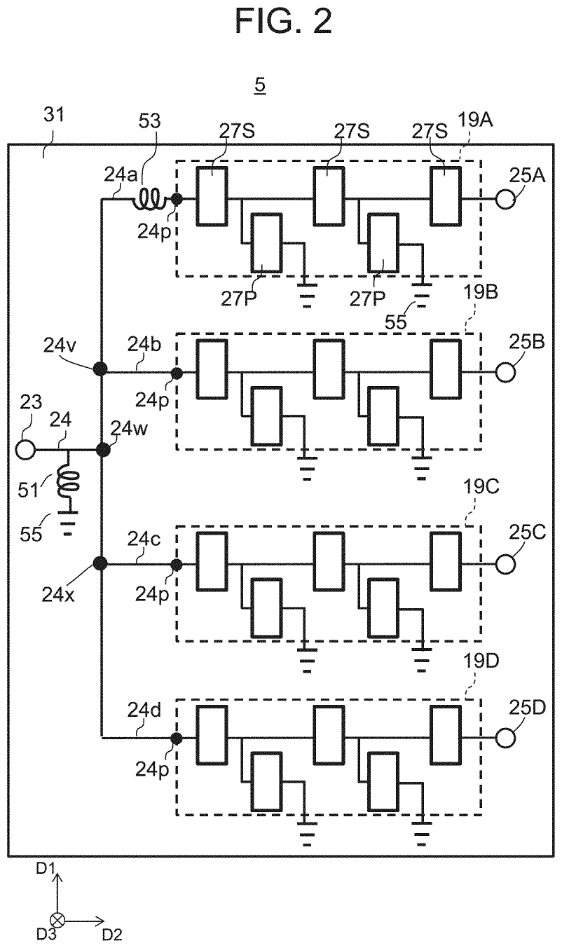

FIG. 2 is a schematic view showing the configuration of the principal parts in the filter device 5. The filter device 5 for example has an antenna terminal 23 connected to the antenna 3 side, a plurality of (four in the example shown) filters including a first filter 19A to fourth filter 19D which are connected to the antenna terminal 23, and input and/or output ports 25 (25A to 25D) each connected to any one of the filters 19. Each of the filter 19 extracts a signal having predetermined frequency band (passing band) from an input electrical signal and output the result. The passing bands of the plurality of filters 19 are different from each other. Further, each of the filters 19 may be either a transmission filter or reception filter.

Amplifiers (low noise amplifiers: LNA) etc. may be connected between the filters 19 and the input and/or output ports 25 as well. Further, the input and/or output ports 25 of the filters 19 may be individually connected to the RF-IC 7 or may be combined into one and then connected to the RF-IC 7.

The plurality of filters 19 are branched from each other when viewed from the antenna terminal 23. Specifically, for example, the antenna terminal 23 and the plurality of filters 19 are connected by a wiring 24. The wiring 24 are branched in the process of extension from the antenna terminal 23 to the plurality of filters 19. In the wiring 24, parts which are branched and correspond to only single filters 19 will be referred to as the “branched wirings 24a to 24d”. In the example shown, the wiring 24 is branched into two at a branch point 24w. Further, the two branched wirings are branched to the branched wirings 24a to 24d at branch points 24v and 24x.

Note that, unlike the example shown, for example, one wiring may be branched to four branched wirings 24a to 24d at one branch point as well.

Further, the filter device 5 has a common inductor 51 which is provided common to the plurality of filters 19 and an individual inductor 53 which is individually provided with respect to part (19A in the example shown) among the plurality of filters 19. Further, the filter device 5 has a reference potential part 55 which is utilized for giving a reference potential to the filters 19 and common inductor 51. The reference potential part 55, for example, although not particularly shown, is configured including a terminal given the reference potential from an external portion (for example a circuit board on which the filter device 5 is mounted) and including a wiring connected to the terminal. Due to this, the reference potential part 55 will be sometimes referred to as the “reference potential terminal (ground terminal) 55”.

(Example of Configuration of Filter)

Each filters 19 may be for example configured by a so-called ladder type resonator filter. A ladder type resonator filter has a plurality of (may be one) serial resonators 27S which are connected in series between the antenna terminal 23 and the input and/or output port 25 and a plurality of (may be one) parallel resonators 27P (parallel arms) which connect the above serial line (serial arm) and reference potential part 55 (below, sometimes they will be simply referred to as the “resonators 27” and the two will not be differentiated).

The plurality of serial resonators 27S are basically made equal in resonance frequency to each other and are made equal in antiresonance frequency to each other. The plurality of parallel resonators 27P are basically made equal in resonance frequency to each other and are made equal in antiresonance frequency to each other. Further, the resonance frequency of the serial resonators 27S and the antiresonance frequency of the parallel resonators 27P are made substantially equal to each other. Due to this, a filter having a passing band is configured. The passing band is a range of frequency which is somewhat narrower than the frequency range from the resonance frequency of the parallel resonators 27P to the antiresonance frequency of the serial resonators 27S.

Note that, the number of serial resonators 27 and number of parallel resonators 27P may be suitably set for each of the filters 19. Further, whether the resonator 27 positioned closest to the antenna terminal 23 side or closest to the input and/or output port 25 side is a serial resonator 27S or a parallel resonator 27P may be suitably set for each of the filters 19.

Further, in this example, an explanation was given of the example of configuring the filters 19 by ladder type resonator filters. However, for example, the filters 19 may be multimode type acoustic wave filters as well. Note that, in the present disclosure, the “multimode” includes a double mode. Further, filters forming one passing band by combining multimode type filters and ladder type resonator filters may be used as well.

(Configuration of Resonator)

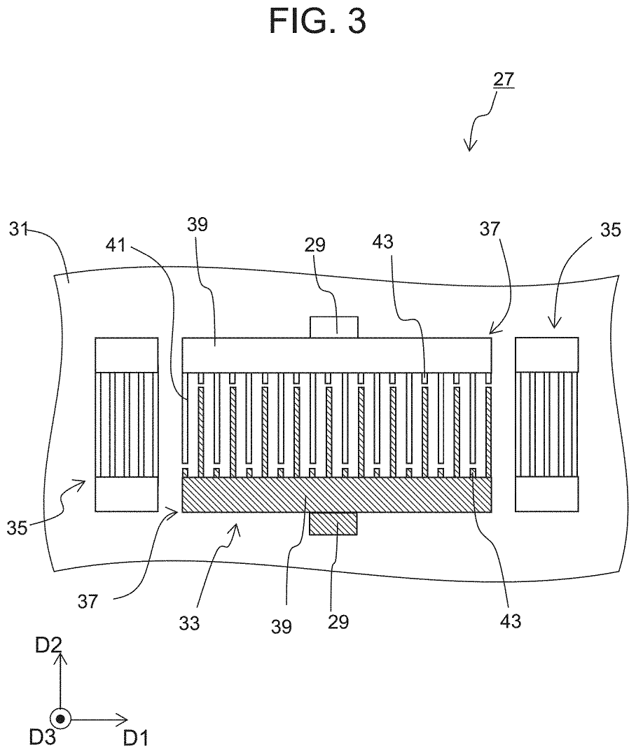

FIG. 3 is a schematic plan view showing the configuration of the principal parts in each resonator 27

Note that, in the resonator 27, any direction may be defined as “above” or “below”. In the following explanation, however, for convenience, an orthogonal coordinate system comprised of a D1 axis, D2 axis, and D3 axis will be defined, and sometimes the “upper surface” or “lower surface” and other terms will be used where the positive side in the D3 axis is the upper part. Further, when referring to “viewed on a plane”, it means “viewed in the D3 axis direction” when not particularly explained otherwise. Note that, the D1 axis is defined so as to be parallel to the direction of propagation of the SAW propagating along the upper surface of the piezoelectric substrate which will be explained later, the D2 axis is defined so as to be parallel to the upper surface of the piezoelectric substrate and perpendicular to the D1 axis, and the D3 axis is defined so as to be perpendicular to the upper surface of the piezoelectric substrate.

The resonator 27 is for example configured by a SAW resonator utilizing a surface acoustic wave (SAW). More specifically, the resonator 27 is configured by for example a so-called 1 port SAW resonator. When an electrical signal is input from one of two wirings 29 shown on the two sides of the drawing sheet in the vertical direction (any one of the wirings 29 is configured by the wiring 24 in FIG. 2 according to the position of the resonator 27), SAW resonator 27 resonates at a predetermined frequency and outputs the resonating signal to the other of the two wirings 29.

The resonator 27 for example includes a piezoelectric substrate 31, an IDT (interdigital transducer) electrode 33 which is provided on the upper surface of the piezoelectric substrate 31, and a pair of reflectors 35 which are positioned on the two sides of the IDT electrode 33.

The piezoelectric substrate 31 is for example configured by a single crystal having a piezoelectric characteristic. The single crystal is for example comprised of lithium tantalate (LiTaO₃), lithium niobate (LiNbO₃), or quartz crystal (SiO₂). The cut angle, planar shape, and various dimensions of the piezoelectric substrate 31 may be suitably set. A first substrate may be bonded to the lower surface of the piezoelectric substrate 31 for compensating for a change of characteristic of the resonator 27 due to a temperature change as well. Further, between the piezoelectric substrate 31 and the first substrate, a multilayer film may be positioned, or an inorganic film comprised of SiO₂ or the like may be positioned.

The IDT electrode 33 and reflectors 35 are configured by layered conductors which are provided on the piezoelectric substrate 31. The IDT electrode 33 and reflectors 35 are for example configured by mutually the same materials to same thickness. The layered conductors configuring them are for example Al or another metal. The layered conductor may be configured by a plurality of metal layers as well. The thickness of the layered conductors is suitably set in accordance with the electrical characteristics etc. demanded from the resonator 27. As one example, the thickness of the layered conductors is 50 nm to 600 nm.

The IDT electrode 33 includes a pair of comb-shaped electrodes 37. Note that, for improving visibility, hatching is attached to one comb-shaped electrode 37. Each comb-shaped electrode 37 includes a bus bar 39, a plurality of electrode fingers 41 extending from the bus bar 39 alongside each other, and dummy electrodes 43 which projecting from the bus bar 39 between two or more electrode fingers 41. The pair of comb-shaped electrodes 37 are arranged so that the pluralities of electrode fingers 37 intermesh (intersect) with each other.

Each electrode finger 41 for example linearly extends in a direction (D2 axis direction) perpendicular to the direction of propagation of the SAW with a constant width. The plurality of electrode fingers 41 in one comb-shaped electrode 37 and the plurality of electrode fingers 41 in the other comb-shaped electrode 37 are basically alternately arranged in the direction of propagation of the SAW. The pitch “p” of the plurality of electrode fingers 41 (for example the distance between the centers of two mutually neighboring electrode fingers 41) is basically constant in the IDT electrode 33.

Note that, the number, length, width, etc. of the electrode fingers 41 may be suitably set in accordance with the electrical characteristics etc. demanded from the resonator 27. Note that, FIG. 3 is a schematic view, therefore a smaller number of electrode fingers 41 are shown. The IDT electrode 33 may be apodized or may be one not having dummy electrodes 43. Further, a portion of the IDT electrode 33 may have a narrow pitch part or broad pitch part.

The reflectors 35 are for example formed in lattice shapes having pluralities of strip electrodes (notation omitted) extending in a direction perpendicular to the direction of propagation of the SAW. The pitch thereof is equal to the pitch of the electrode fingers 41 in the IDT electrode 33. The intervals between the reflectors 35 and the IDT electrode 33 are for example equal to the pitch of the electrode fingers 41. Each reflector 35 for example may be made an electrically floating state or may be given the reference potential.

Note that, although not particularly shown, the upper surface of the piezoelectric substrate 31 may be covered by a protective film made of SiO₂ or Si₃N₄ or the like from the tops of the IDT electrode 33 and reflectors 35 as well. The protective film may be one for reducing corrosion of the IDT electrode 33 etc. or may be one contributing to temperature compensation. Further, in a case where the protective film is provided etc., the upper surfaces or lower surfaces of the IDT electrode 33 and reflectors 35 may be provided with additional films formed by an insulator or metal in order to improve the reflection coefficient of the SAW.

When a voltage is applied to the upper surface of the piezoelectric substrate 31 by the IDT electrode 33, a SAW propagating in the D1 axis direction at the upper surface of the piezoelectric substrate 31 is excited, and a standing wave of the SAW having the pitch “p” as a half wavelength stands.

The signal generated according to this standing wave is extracted by the IDT electrode 33. In this way, resonance in the resonator 27 is utilized. The resonance frequency of the resonator 27 becomes substantially equal to the frequency of the standing wave (SAW having the pitch “p” as a half wavelength). The antiresonance frequency is determined according to the resonance frequency and the capacity ratio, while the capacity ratio is mainly defined by the piezoelectric substrate 31 and is adjusted according to the number, intersecting width, film thickness, etc. of the electrode fingers 41.

(Example of Configuration of Inductor)

The common inductor 51 is arranged between the wiring 24 and the reference potential part 55. In other words, the common inductor 51 is connected in parallel with respect to the wiring 24. The connection position of the common inductor 51 with respect to the wiring 24 is within a range from the antenna terminal 23 to the branch point 24w. The inductance of the common inductor 51 may be suitably set.

The individual inductor 53 is connected between the branch point 24v branching the first filter 19A independently from the other filters 19 and the first filter 19A (the later explained point 24p). The individual inductor 53, in other words, is connected in series on the front stage side of the first filter 19A when viewed from the antenna terminal 23. The inductance of the individual inductor 53 may be suitably set.

For obtaining the inductances in the common inductor 51 and individual inductor 53, use is made of a chip element, wirings on the piezoelectric substrate 31, wirings provided on an insulator such as a resin provided on the piezoelectric substrate 31, etc. As an example of provision on an insulator, for example, a case of placing a cover of an insulator which is placed on the piezoelectric substrate 31 and protects the resonators 27 and obtaining the inductances by the wiring patterns arranged inside or above the cover can be exemplified. This cover may be one forming a space between the cover and the piezoelectric substrate and accommodating the resonator 27 inside. Further, when the piezoelectric substrate 31 is mounted on a mounting board, it may be formed by the wirings on the mounting board side. Specifically, use may be made of a multilayer ceramic board or multilayer organic substrate as the mounting board. Conductor patterns manifesting inductances may be arranged between layers of dielectric films.

(Transmission Characteristic of Filter Device)

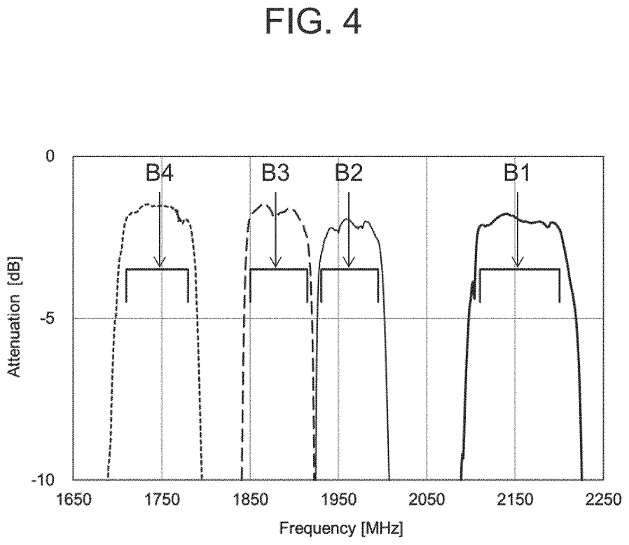

FIG. 4 is a graph showing the passing bands and transmission characteristics of the filter device 5. In this graph, an abscissa shows the frequencies, and an ordinate shows the transmission characteristics (unit: dB).

In this graph, a passing band B1 of the first filter 19A, a passing band B2 of the second filter 19B, a passing band B3 of the third filter 19C, and a passing band B4 of the fourth filter 19D are shown. In the example shown, the passing bands B1, B2, B3, and B4 are shown in order from the highest frequency.

In FIG. 4, the transmission characteristic of the filter 19A is indicated by a wide solid line, the transmission characteristic of the filter 19B is indicated by a thin solid line, the transmission characteristic of the filter 19C is indicated by a broken line, and the transmission characteristic of the filter 19D is indicated by a dotted line.

The transmission characteristics shown in FIG. 4 are obtained from computer simulations. As shown in FIG. 4, the transmission characteristic becomes high in the passing band and becomes low out of the passing band. The specific values thereof may be suitably set in accordance with the required specifications etc.

Further, in the example shown, the passing bands B2 to B4 are relatively close to each other, while the passing band B1 is relatively separate from the passing bands B2 to B4. As one example, the passing bands B2 to B4 fall in a range of 1700 MHz to 2020 MHz, and the passing band B1 falls into a range of 2100 MHz to 2250 MHz. Further, for example, a frequency difference between the passing band B1 and the passing band among the passing bands B2 to B4 which is closest to the passing band B1 is larger than the frequency difference between mutually neighboring passing bands among the passing bands B2 to B4. Here, the frequency difference, in neighboring passing bands, means a difference between the frequency on the highest frequency side in the passing band on a lower frequency side and the frequency on the lowest frequency side in the passing band on a higher frequency side. Further, for example, the frequency difference between the passing band B1 and the passing band among the passing bands B2 to B4 which is closest to the passing band B1 may be made larger than the bandwidth of any of the passing bands B1 to B4 as well.

(Impedance of Filter Device)

The impedance characteristic in each of the filters 19 will be studied. The plurality of filters 19 are connected at one branch point 24w. Therefore, inherently, in order to match with the antenna terminal 23, an individual matching circuit etc. must be provided for each of the filters 19. Further, sometimes a matching circuit for overall matching was provided between the branch point 24w and the antenna terminal 23. However, if these matching circuits were provided, an increase in size of the apparatus was invited and the consumed power etc. increased so loss was liable to occur.

Therefore, according to the present disclosure, conductances when viewing the antenna terminal 23 side from the filters 19 are made the same in front of the branch point 24w, and all the filters 19 are moved to the standard point (generally 50Q) together by the common inductor 51, thereby matching is obtained. Here, in order to make the conductances uniform in front of the branch point 24w, the individual inductor 53 is connected in series with respect to a specific filter 19 and connected between the branch point 24w (24v) and the filter 19 (19A).

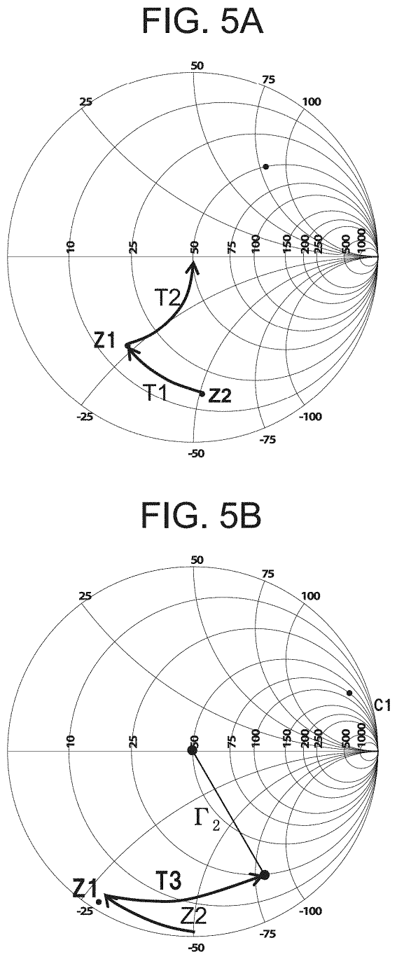

FIG. 5A and FIG. 5B show conceptual views of impedance when viewed from the antenna terminal 23 side in a filter 19 (19A) to which an individual inductor 53 is connected. FIG. 5A is a Smith chart showing impedance values when viewed from the antenna terminal 23 side at the passing band frequency (more specifically a center frequency of the passing band). Here, “from the antenna terminal 23 side” means the “direction viewed in terms of the circuit”. The “susceptance of the filter 19 when viewed from the antenna terminal 23 side” indicates the “susceptance when viewing the filter 19 from the point 24p at which the filter 19 is connected to the wiring on the antenna terminal 23 side”.

As shown in FIG. 5A, the impedance of the filter 19 moves in a constant resistance circle from Z2 to the vicinity of Z1 by a trace T1 by the individual inductor. Here, when comparing the susceptances in the filters 19 at center frequencies of their own passing bands when viewed from the antenna terminal 23 side, the specific filter 19 connected with the individual inductor 53 is smaller in susceptance compared with at least one among the other filters 19. That is, it takes the impedance value Z2. For this reason, the impedance of the filter 19 to which the individual inductor 53 is connected (that is, the impedance when viewing the filter 19A side from the branch point 24v), compared with that before connection, can be made closer to the impedance value (Z1) of the filter 19 having a larger susceptance among the other filters 19. The number of the filters 19 having larger susceptances among the other filters 19 is preferably two or more.

Note that, below, sometimes the “susceptance of the filter 19 when viewed from the antenna terminal 23 side” will be simply described as the “susceptance of the filter 19”.

In this way, after adjustment making the impedance values of the filters 19 closer before the branch point 24w, the impedance can be moved with a trace T2 up to the standard point of the Smith chart along the constant conductance circle.

On the other hand, as shown in FIG. 5B, in the frequency band other than its own passing band, the impedance value of the filter 19A is positioned at Z2. Z2 is separated from the standard point of the Smith chart, so the reflection coefficient is high. Even if the impedance value moves from Z2 positioned in the vicinity of the periphery of the Smith chart to the vicinity of the impedance value Z1 due to the individual inductor 53 and moves by a trace T3 by the common inductor 51, as indicated by Γ2, a high reflection coefficient can be maintained in the passing bands of the other filters.

Note that, even if the high reflection coefficient is maintained, the reflection coefficient of the filter 19 connected with the individual inductor 53 becomes somewhat smaller compared with that before the connection. That is, at the stage of moving from Z2 along the constant resistance circle and the stage of moving from Z1 along the constant conductance circle, the distance up to the standard point becomes somewhat smaller. Here, where use is made of a resonator using the SAW as shown in FIG. 3 as the filter 19, the loss becomes larger and the reflection coefficient tends to become smaller on a high frequency side out of the band. For this reason, by connecting the individual inductor 53 to the filter provided with the passing band on the highest frequency side, the effect due to the reflection coefficient becoming smaller can be reduced.

In the present embodiment, each of the plurality of filters 19 includes an acoustic wave filter having a piezoelectric substrate 31 and an excitation electrode (IDT electrode 33) positioned on the piezoelectric substrate 31.

The excitation electrode in the acoustic wave filter includes a pair of electrodes (for example pair of comb-shaped electrodes 37) which face each other so as to apply voltage to the piezoelectric substrate 31 to generate an acoustic wave, therefore the impedance of the filter 19 easily becomes capacitive when away from the passing band. Accordingly, the effects explained with reference to FIG. 5A and FIG. 5B become easily exerted.

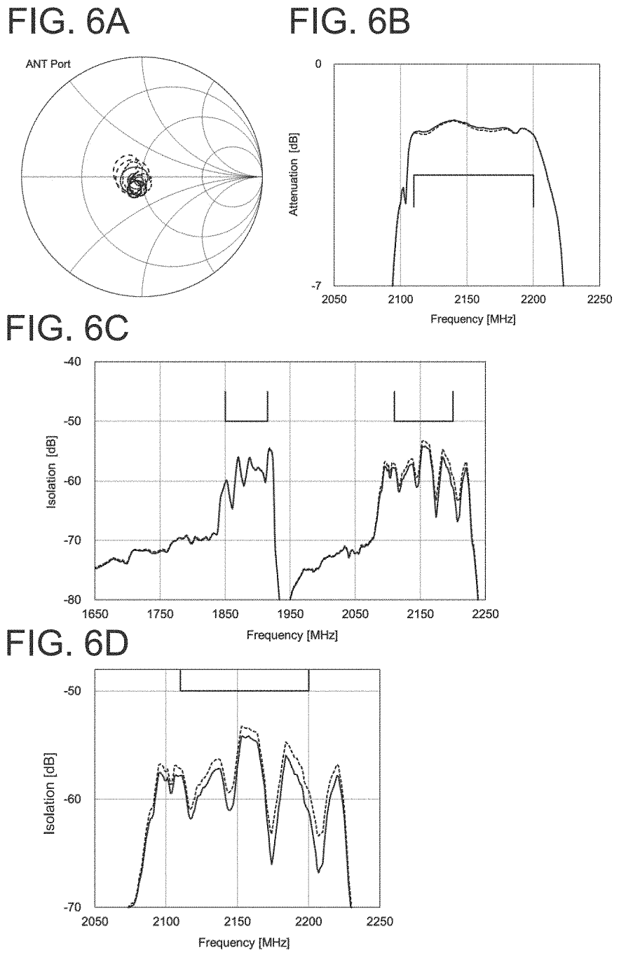

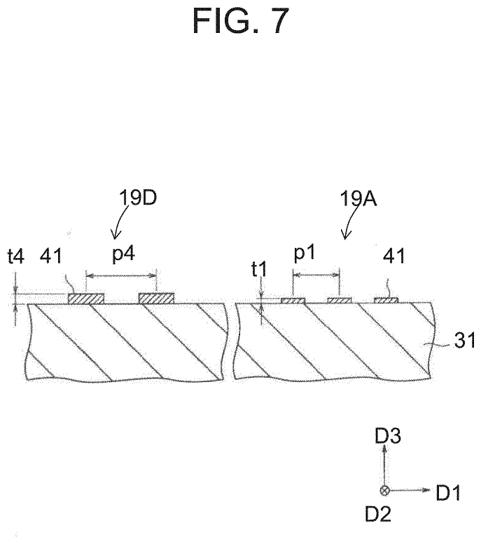

Next, the results of simulations for the filters 19 having the passing bands B1 to B4 shown in FIG. 4 will be shown in FIGS. 6A to 6D. The fundamental conditions of simulation were as follows. Note that, in order to evaluate the impedance characteristics of the filters 19, for convenience, the admittance Y (unit: Ω⁻¹) is employed. The admittance Y is indicated by Y=G+jB. Here, G indicates a conductance, and B indicates a susceptance.

[Fundamental Conditions]

### First Filter 19A:

Receiving filter, Y at the center frequency of B1 is equal to 0.0180+j0.0469

### Second Filter 19B:

Receiving filter, Y at center frequency of B2 is equal to 0.0300+j0.0430

### Third Filter 19C:

Transmission filter, Y at center frequency of B3 is equal to 0.0198+j0.0512

### Fourth Filter 19D:

Transmission filter, Y at center frequency of B4 is equal to 0.0157+j0.0550

Common inductor 51: 1.7 nH
Individual inductor 53: 0.2 nH

The susceptance of the first filter 19A to which the individual inductor 53 is connected becomes smaller than the susceptances of the third filter 19C and fourth filter 19D. Further, as explained before, the passing band of the first filter 19A becomes the highest frequency.

FIG. 6A, in the Smith chart, shows the impedance characteristics when viewed from the antenna terminal 23 side in the entire device when connecting the filters 19 to the antenna terminal 23. In the chart, the characteristic of the filter 19A is indicated by the wide solid line, the characteristic of the filter 19B is indicated by the thin solid line, the characteristic of the filter 19C is indicated by the broken line, and the characteristic of the filter 19D is indicated by the dotted line. It was confirmed that all filters 19 were present at the standard point with a good convergence degree. Note that, before connecting the individual inductor 53, they are converged at positions somewhat offset from the standard point, and the convergence degrees were somewhat inferior.

Here, the susceptance of the second filter 19B has a smaller value than the susceptance of the first filter 19A. However, a filter having a lower frequency of a passing band can be moved more to the standard point side by the common inductor 51, therefore the individual inductor 53 is connected to the first filter 19A. Due to this, compared with a case where the individual inductor is provided in the second filter 19A, but is not provided in the first filter 19A, the deviation from the standard point when viewed in the entire device becomes smaller.

FIG. 6B shows the transmission characteristic of the first filter 19A. In the graph, the abscissa shows the frequency (unit: MHz), the ordinate shows the transmission characteristic (unit: dB), the broken line indicates the transmission characteristic where the individual inductor 53 is not provided (below, referred to as the “reference”), and the solid line indicates the transmission characteristic where the individual inductor 53 is provided (below, referred to as the “example”).

As apparent also from FIG. 6B, it can be confirmed that the transmission characteristic in the passing band B1 is improved in the example compared with the reference. The reason for this is believed to be that matching was obtained by insertion of the individual inductor 53.

Note that, by confirmation of the VSWR of the first filter 19A and the convergence degree of the impedance in the same way, the improvement of the characteristics of the two in the example compared with the reference was confirmed.

Next, the isolation characteristics of the filters 19 were simulated. As a representative, the results of computation of isolation between the first filter 19A and the third filter 19C will be shown in FIG. 6C. Further, FIG. 6D shows an enlarged chart of the principal parts in FIG. 6C. In the graph, the abscissa shows the frequency (unit: MHz), the ordinate shows the isolation characteristic (unit: dB), the broken line indicates the isolation characteristic of a reference, and the solid line shows the isolation characteristic of an example.

As apparent also from the graph, the example is improved in isolation compared with the reference. Specifically, an improvement of 0.9 dB at the frequency of the passing band B1 of the first filter 19A was confirmed. Note that, when checking the transmission characteristic of the third filter 19C, there is no change in the position of the attenuation pole etc. of the third filter 19C, therefore it is deduced that the isolation characteristic was improved by the individual inductor 53.

Further, although not shown, when confirming the isolation characteristics between the first filter 19A and the fourth filter 19D, it was seen that the isolation characteristic was improved in the band B1. Further, it could be confirmed that the isolation characteristics of the filters other than the first filter 19A were also improved. Specifically, it could be confirmed that the isolation characteristic between the second filter 19B and the third filter 19C were improved in both of the bands B2 and B3 and also that the isolation characteristic between the second filter 19B and the fourth filter 19D were improved particularly in the band B2.

As explained above, by connecting the individual inductor 53 in series to a specific filter 19 and connecting in parallel the common inductor 51 which is common with respect to all the filters 19 between the branch point 24w and the antenna terminal 23, the plurality of filters 19 can simultaneously be matched. Further, due to the individual inductor 53, the VSWR is improved and matching is possible, therefore loss related the filter 19 connected with the individual inductor 53 falls, and the isolation characteristic is improved.

(Modification of Filter Connected With Individual Inductor)

In the example explained above, the example of connecting the individual inductor 53 to the filter 19 having the highest frequency passing band (first filter 19A) and the filter 19 at which the susceptance at the center frequency of its own passing band is not the maximum among the plurality of filters 19 was explained. However, the present invention is not limited to this.

That is, there may be restrictions not only in the susceptance of the filter 19, but also in the capacity characteristic of that. Specifically, the individual inductor 53 may be connected to a filter other than the filter in which the combined capacity of the resonator positioned on the side closest to the antenna terminal 23 is the smallest among the plurality of filters 19. More preferably, the individual inductor 53 may be connected to the filter 19 in which the combined capacity of the resonator positioned on the side closest to the antenna terminal 23 is the maximum as well. By connecting the individual inductor 53 to such a filter 19, adjustment can be carried out so that the impedance values at the center frequencies can be made closer among the plurality of filters 19.

Further, in the same way as the conditions of the simulations shown in FIGS. 6A to 6D, when the transmission filter and the reception filter are mixed in the filter 19, the individual inductor 53 may be provided with respect to the reception filter as well. This is because the power of the transmission filter is larger compared with the power of the reception filter, therefore the individual inductor 53 reduces mixing of a leakage signal from the transmission filter. Further, in particular, desirably the susceptance of the transmission filter is larger compared with the susceptance of the filter connected with the individual inductor 53 in order to adjust the impedance between the later filter and the transmission filter. Conversely speaking, when there is a filter 19 having a smaller susceptance than the filter connected with the individual inductor 53 among the plurality of filters 19, the former filter may be employed as the reception filter as well.

(Other Modification)

### (Common Use of Piezoelectric Substrate)

Return to FIG. 2. In this view, the entireties of the IDT electrode 33 and the pair of reflectors 35 sandwiching the IDT electrode 33 are shown by squares. Further, the piezoelectric substrate 31 is also schematically shown.

In each filter 19, the plurality of resonators 27 are for example provided on a common piezoelectric substrate 31. Further, the plurality of filters 19 are for example provided on a common piezoelectric substrate 31. That is, the plurality of filters 19 share the piezoelectric substrate 31 while having their respective IDT electrodes 33. The antenna terminal 23 and input and/or output port 25 are for example provided on the piezoelectric substrate 31.

Note that, in a planar view of the piezoelectric substrate 31, the arrangements of the antenna terminal 23, the input and/or output port 25, and the plurality of resonators 27 may be suitably set. FIG. 2 is only a schematic view. The plurality of filters 19 need not be arranged in a line like illustrated, the serial resonators 27S need not be arranged in a line in each filter 19, and the plurality of parallel resonators 27P need not be positioned on the same side (lower part side on the drawing sheet) relative to the plurality of serial resonators 27S in each filter 19.

(Electrode Film Thickness)

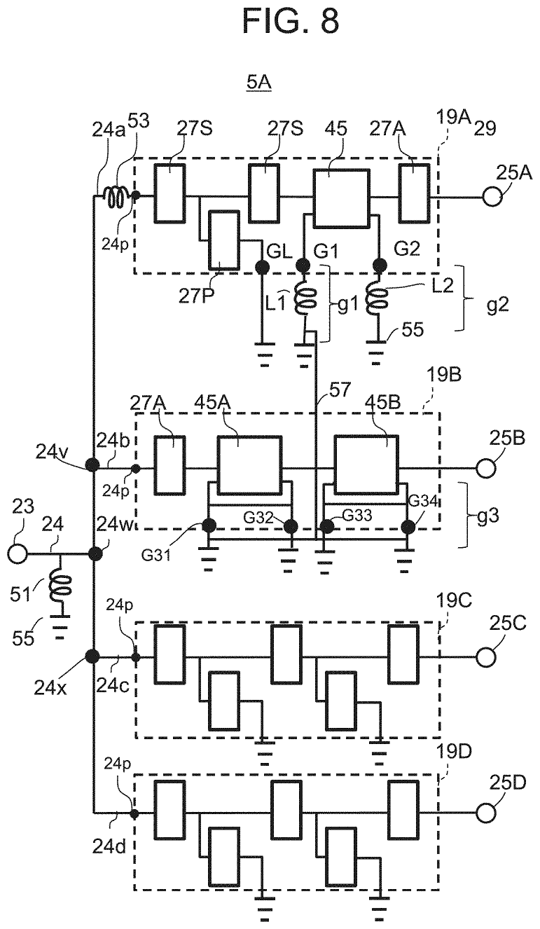

FIG. 7 is a cross-sectional view showing a part of the upper surface of the piezoelectric substrate 31. In this view, a part of the first filter 19A and a part of the fourth filter 19D are shown.

In general, the film thicknesses of the IDT electrode 33 and reflectors 35 formed on the same piezoelectric substrate 31 (below, electrode film thicknesses) are the same among the plurality of resonators 27. However, as illustrated, the electrode film thicknesses may differ among the plurality of filters 19 as well. Specifically, for example, the electrode film thickness of at least one filter 19 may be made thinner than the electrode film thickness of at least one other filter 19 having a lower frequency of passing band (having a larger pitch p from another viewpoint) than the former filter 19.

In the present embodiment, the first filter 19A, the second filter 19B, the third filter 19C, and the fourth filter 19D have higher passing bands in this order. Accordingly, for example, the pitch μl of the first filter 19A is smaller than the pitch p4 of the fourth filter 19D. Further, in FIG. 7, an electrode film thickness μl of the first filter 19A is made thinner than an electrode film thickness t4 of the fourth filter 19D.

The difference of the two is for example 20 nm to 200 nm. Note that, the electrode film thickness optimum for each frequency band differs depending on the material of the piezoelectric substrate or cut angle. However, for example it is set to substantially 6% to 9% of the wavelength (two times the pitch) in a case of a 42° Y-cut and X-propagation lithium tantalate (LT) substrate. In this way, the pitch differs according to the difference of the pass band frequency. The electrode film thickness is also suitably set. By adjusting the pitch and electrode film thickness and setting the optimum combination, filters which are originally prepared with different cut angles of the LT substrates due to very different passing bands can be prepared on the same substrate. Further, even if a plurality of filters are formed in the substrate having the same cut angle, by making the electrode film thicknesses differ by 20 nm or more in this way, the filter characteristics can be maintained well. For example, by somewhat shifting the frequencies of the passing bands from the frequency band where the phase characteristic of another band deteriorated, the reflection coefficient can be raised and the loss can be reduced.

Such a difference of electrode film thicknesses may be realized by for example forming the IDT electrode 33 in the first filter 19A and the IDT electrode 33 in the fourth filter 19D by different processes or forming the IDT electrode 33 in the first filter 19A and a lower part the IDT electrode 33 in the fourth filter 19D in the same process, then forming an upper part of the IDT electrode 33 in the fourth filter 19D. The IDT electrodes 33 having film thicknesses different from each other for example just differ in film thicknesses, and are configured by the same materials as each other.

Note that, the electrode film thicknesses of the plurality of filters 19 may be different from each other among all of the filters 19 so that the filter having a higher frequency of the passing band becomes thinner in electrode film thickness or the electrode film thicknesses of two or three filters 19 among them (filters having frequencies of passing bands closest to each other) may be made the same as each other.

(Modification: Filter Device 5A)

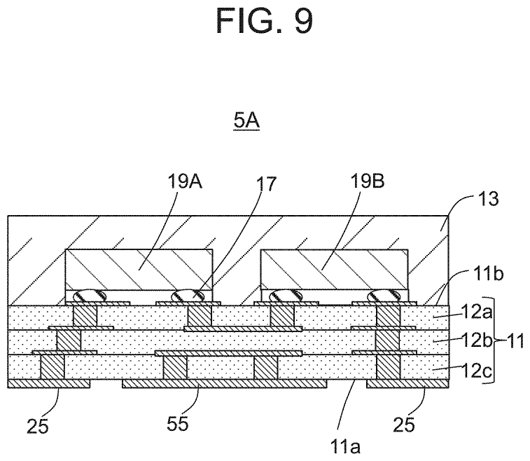

In FIG. 2, the explanation was given by taking as an example the case where all of the plurality of filters 19 were ladder type filters. However, as shown in FIG. 8, some of the filters 19 may be configured by longitudinally coupled type filters 45 (below, also referred to as “DMS filters 45”) or ladder type resonator filters or combinations of them.

Ladder type resonator filters are applied to a part of the first filter 19A, the third filter 19C, and the fourth filter 19D.

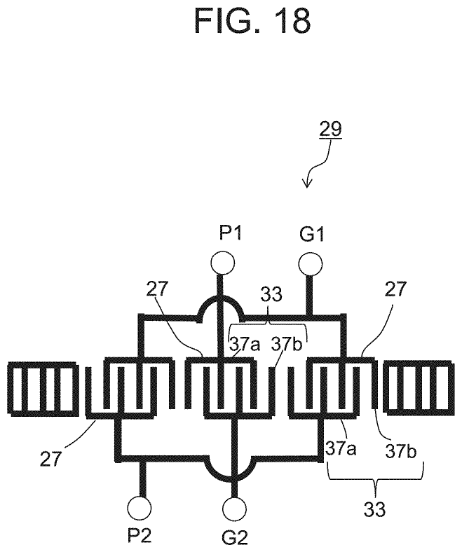

DMS filters 45 are applied to part of the first filter 19A and to the second filter 19B. Specifically, the DMS filter 45 is configured with the resonators 27 arranged along the direction of propagation of the acoustic wave. In this, a signal is transferred to a resonator 27 neighboring a resonator 27 receiving the signal as input. The signal is output from a resonator 27 which is different from the resonator 27 receiving the signal as input (see FIG. 18 which will be explained later). The number of resonators is not particularly limited so far as it is three or more. Further, the resonators 27 are electrically connected to the ground terminal 55. Specifically, the DMS filter 45 is provided with a ground port G1 positioned on the antenna terminal 23 side and a ground port G2 positioned on the input and/or output port 25 side. The ground ports are connected to the ground terminal 55.

Further, each filter 19 may include a resonator 27A other than the resonators configuring the ladder type resonator filter and DMS filter as well.

In this case as well, it becomes possible to adjust the impedance by the common inductor 51 and individual inductor 53.

Further, in this example, the attenuation characteristic of the filter can be controlled by the method of interconnecting the first filter 19A and second filter 19B to the reference potential. Below, the configuration thereof will be explained.

(Connection of Ground Wiring)

Here, connection routes of the first filter 19A (first acoustic wave filter) and second filter 19B (second acoustic wave filter) to the ground terminal 55 will be explained.

The first filter 19A is configured by the ladder type resonator filter and the DMS filter 45 being connected in order from the antenna terminal 23 side. Further, the ladder type resonator filter is provided with a ground port GL which is connected to a parallel resonator 27P of that, while the DMS filter 45 is provided with the ground port G1 (first ground port) which is positioned on the antenna terminal 23 side (input side) and with the ground port G2 (second ground port) which is positioned on the side of connection to the input and/or output port (first terminal) 25A (output side). These ground ports GL, G1, and G2 are electrically connected to the ground terminal 55. Note that, in the first filter 19A, these ground ports GL, G1, and G2 are independent from each other.

In the same way, the second filter 19B is also provided with a ground port G3 (third ground port) electrically connected to the ground terminal 55. In this example, the ground port G3 is configured including either of a ground port positioned on the input side or a ground port positioned on the output side of the DMS filter 45 configuring the second filter 19B. More specifically, the ground port G3 is configured by at least one of the ground ports G31 to G34 on input sides and output sides of a DMS filter 45A and a DMS filter 45B which configure the second filter 19B and are connected to each other. Note that, in this example, the ground ports G31 and G32 are given the same potential, and the ground ports G33 and G34 are given the same potential.

Here, the connection route from each filter 19 to the ground terminal 55 will be focused on. In an intermediate position of a route g1 from the first ground port G1 to the ground terminal 55, a first inductor L1 is serially connected. In the same way, a second inductor L2 is serially connected in an intermediate position of a route g2 from the second ground port G2 to the ground terminal 55. Further, provision is made of a ground wiring 57 which electrically connects either of the ground terminal 55 side in the first inductor L1 or the ground terminal 55 side in the second inductor L2 and a route g3 from the third ground port G3 to the ground terminal 55.

Such a ground wiring 57 makes it possible to adjust the impedances of the first filter 19A and second filter 19B. Details will be explained later.

(Configuration of Filter Device)

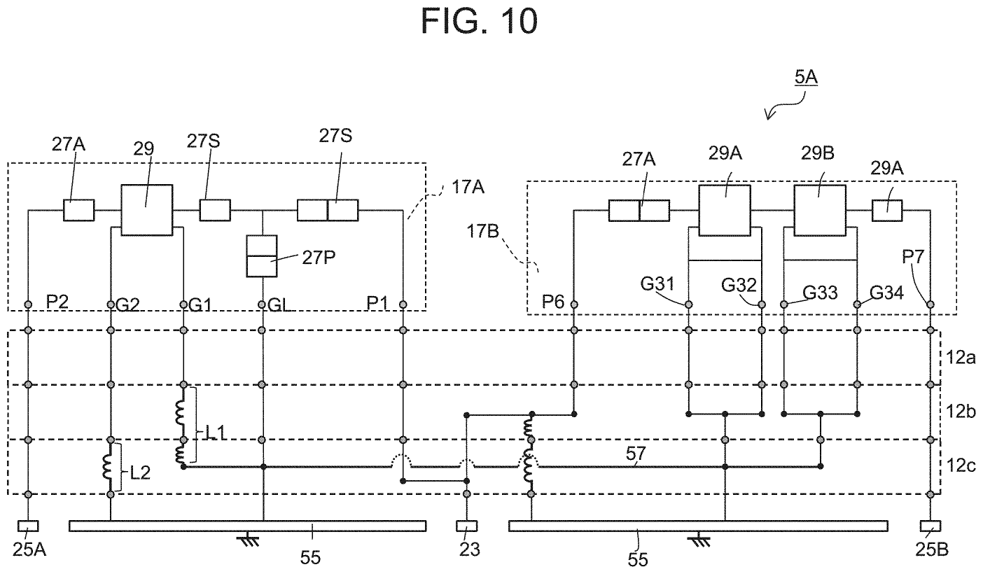

A specific configuration of a filter device 5A will be explained by using FIGS. 9 to 11. FIG. 9 is a cross-sectional view of an embodiment of the filter device 5A. The filter device 5A is provided with a structure 11, filters 19, and an insulation member 13.

The structure 11 is configured by stacking a plurality of dielectric layers 12. In this example, the structure 11 includes three layers of the dielectric layer 12a to dielectric layer 12c. Further, on the lower surface of the dielectric layer 12c configuring a first surface 11a of the structure 11, conductor patterns configuring various terminals etc. (23, 25 and 55) are formed. On the upper surface of the dielectric layer 12a configuring a second surface 11b, conductor patterns corresponding to the ports of the filters 19 or for mounting the filters 19 are formed. Further, using vias penetrating in the thickness direction of the dielectric layers 12 and using conductor patterns formed on the upper surface of the dielectric layers 12b and 12c, a circuit realizing desired electrical characteristics can be formed between the first surface 11a and the second surface lib in the structure 11.

On the second surface lib of the structure 11, the filters 19 are mounted by bumps 17. Specifically the filters 19 are provided with substrates and groups of electrodes for configuring the resonators 27 and ports formed on the substrates and are mounted so that the surfaces of the substrates on the sides where the groups of electrodes are positioned face the second surface lib across a distance.

Further, the insulation member 13 is formed so as to cover the filters 19 from the second surface 11b of the structure 11. The insulation member 13 may be configured by for example epoxy or another resin material. By the insulation member 13, the filters 19 are protected, and the filters 19 can be sealed in a state where a space is maintained between the filters 19 and the structure 11.

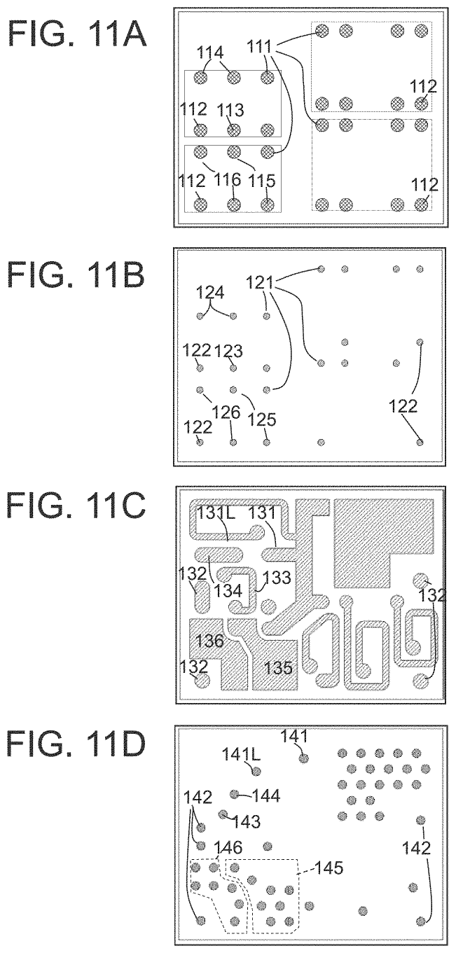

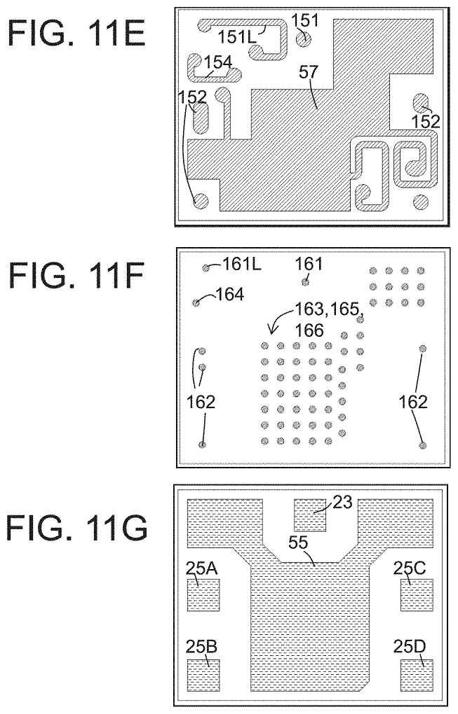

Next, the configuration of the structure 11 will be explained in detail according to FIGS. 10 and 11. FIG. 10 is a view for explaining connection relationships of wirings formed inside the structure 11 etc., and FIG. 11 is a disassembled diagram showing the conductor patterns for each dielectric layer 12 in the structure 11. Note that, in FIGS. 10 and 11, the individual inductor 53 is omitted.

In FIG. 10, the filter 19A is provided with a port P1 connected to the antenna terminal 23, a port P2 connected to the first terminal 25A, a ground port GL, a ground port G1, and a ground port G2.

The filter 19B is provided with a port P6 connected to the antenna terminal 23, a port P7 connected to the input and/or output port 25B (second terminal 25B), and ground ports G31 to G34.

As shown in FIG. 10, the first ground port G1 is connected to the first inductor L1 and then is connected to the ground wiring 57 and electrically connected with the ground terminal 55. The second ground port G2 is electrically connected through the second inductor L2 to the ground terminal 55.

Further, the ground ports G3 (G31 to G34) of the second filter 19B are also electrically connected to the ground wiring 57. This ground wiring 57 is electrically connected to the ground terminal 55.

Next, the conductor patterns formed in the dielectric layers 12 and connection relationships of vias will be explained by using FIGS. 11A to 11F. FIG. 11A shows the upper surface of the dielectric layer 12a, FIG. 11B shows an intermediate position of the thickness of the dielectric layer 12a, FIG. 11C shows the upper surface of the dielectric layer 12b, FIG. 11D shows an intermediate position of the thickness of the dielectric layer 12b, FIG. 11E shows the upper surface of the dielectric layer 12c, FIG. 11F shows an intermediate position of the thickness of the dielectric layer 12c, and FIG. 11G shows the lower surface of the dielectric layer 12c. Further, in FIG. 11A, a region where the filter 19A is arranged is indicated by the thin solid line, a region where the filter 19B is arranged is indicated by the dotted line, a region where the filter 19C is arranged is indicated by the broken line, and a region where the filter 19D is arranged is indicated by a one-dot chain line.

First, a conductor pattern 111 (FIG. 11A) to which the port on the antenna side in each of the filters 19 is connected is connected through a via 121 (FIG. 11B), conductor pattern 131 (FIG. 11C), via 141 (FIG. 11D), conductor pattern 151 (FIG. 11E), and via 161 (FIG. 11F) to the antenna terminal 23 (FIG. 11G). Note that, a part of this antenna line is connected to the ground terminal 55 through lines 131L, 141L, 151L, and 161L.

In the same way, conductor patterns 112 to which the ports on the input and/or output ports 25 side in the filters 19 are connected through vias 122, conductor patterns 132, vias 142, conductor patterns 152, and vias 162 to the first to fourth input and/or output ports 25A to 25D.

Next, the conductor pattern 113 to which the first ground port G1 of the first filter 19A is connected is connected through a via 123, conductor pattern 133 (first inductor L1), via 143, ground wiring 57 and via 163 to the ground terminal 55.

Conductor patterns 114 connected to the second ground port G2 of the first filter 19A are connected through vias 124, a conductor pattern 134, a via 144, wiring pattern 154 (second inductor L2) and via 164 to the ground terminal 55.

Conductor patterns 115 connected to the third ground ports G31 and G32 in the second filter 19B are connected through vias 125, a conductor pattern 135, vias 145, a ground wiring 57, and vias 165 to the ground terminal 55.

Conductor patterns 116 connected to the third ground ports G33 and G34 in the second filter 19B are connected through vias 126, a conductor pattern 136, vias 146, a ground wiring 57, and vias 166 to the ground terminal 55.

By using such conductor patterns and vias, the connection relationships shown in FIG. 10 are realized.

(Adjustment of Impedance Characteristic)

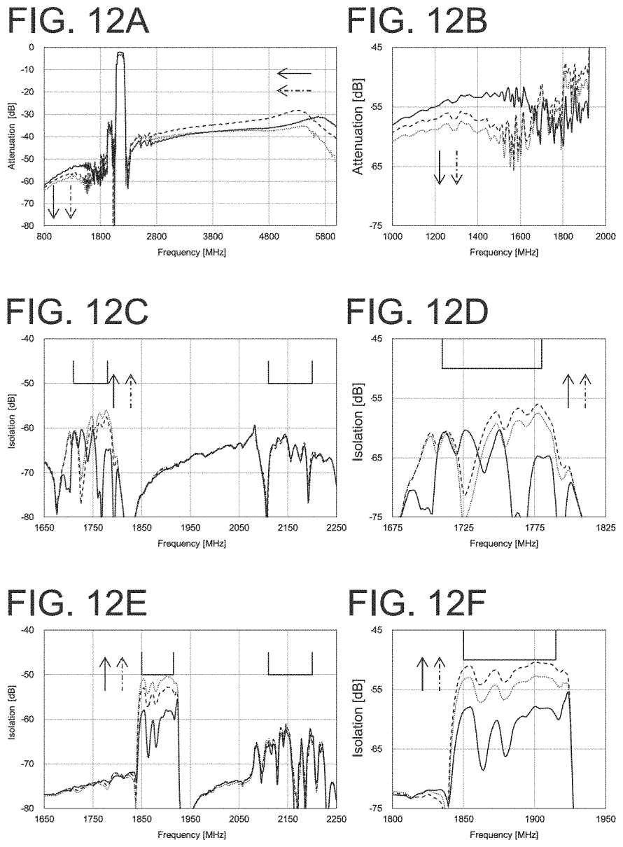

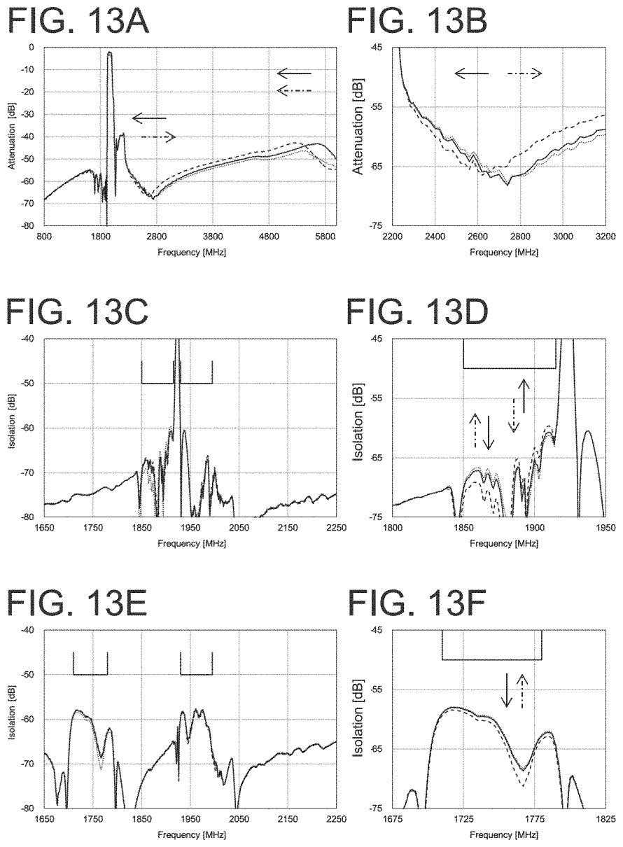

The transmission characteristics of the first filter 19A and second filter 19B were simulated for the filter device 5A shown in FIGS. 10 and 11. Specifically, simulation was carried out for the standard model optimized in design, Modification 1 making the inductance of the first inductor L1 larger than that in this standard model, and Modification 2 making the inductance of the second inductor L2 larger than that in the standard model. The results thereof will be shown in FIG. 12A to FIG. 12F and FIG. 13A to FIG. 13F. In FIG. 12A, FIG. 12B, FIG. 13A, and FIG. 13B, frequencies (unit: MHz) are shown on the abscissas, and transmission characteristics (unit: dB) are shown on the ordinates. In FIG. 12C to FIG. 12F and FIG. 13C to FIG. 13F, frequencies (unit: MHz) are shown on the abscissas, and isolation characteristics (unit: dB) are shown on the ordinates. Further, the characteristics of the standard model are indicated by solid lines, the characteristics of Modification 1 are indicated by broken lines, and the characteristics of Modification 2 are indicated by dotted lines.

Specifically, FIG. 12A shows the transmission characteristics of the first filters 19A, while FIG. 12B is a partially enlarged chart in FIG. 12A. FIG. 12C is a graph showing the isolation characteristics of the first filters 19A from the third filters 19C, while FIG. 12D is a partially enlarged chart of that. FIG. 12E is a graph showing the isolation characteristics of the first filters 19A from the fourth filters 19D, while FIG. 12F is a partially enlarged chart of that.

Further, FIG. 13A shows the transmission characteristics of the second filters 19B, while FIG. 13B is a partially enlarged chart thereof. FIG. 13C is a graph showing the isolation characteristics of the second filters 19B from the third filters 19C, while FIG. 13F is a partially enlarged chart thereof. FIG. 13E is a graph showing the isolation characteristics of the second filters 19B from the fourth filters 19D, while FIG. 13F is a partially enlarged chart thereof.

In the graphs, the trend of change of characteristic of Modification 1 relative to the standard model is indicated by a solid arrow, and the trend of change of characteristic of Modification 2 is indicated by a dotted arrow. As apparent also from the graphs, it was confirmed that the transmission characteristics and isolation characteristics of the first filters 19A changed with the same trend even if the lengths of either of the first inductors L1 or second inductors L2 (magnitudes of the inductances) greatly changed relative to the standard model. That is, if either of the inductors L was made larger, the direction of movement of the attenuation pole was the same (see FIG. 12B, the attenuation pole moved to a low frequency side) and also the trend of improvement or degradation of isolation was the same (see FIG. 12D and FIG. 6F).

On the other hand, the trend of change of characteristic differs in the passing characteristic and isolation characteristic in the second filter 19B between the time when the length of the first inductor L1 (magnitude of inductance) is made larger relative to the standard model and the time when the length of the second inductor L2 (magnitude of the inductance) is made larger. That is, the direction of movement of the attenuation pole differed according to which inductor L is to be made larger (see FIG. 13B) and also the trend of improvement or degradation of isolation was different (see FIG. 13D and FIG. 13F).

From this fact, the positions of the attenuation poles and the attenuation levels at the specific frequency bands of the first filter 19A and second filter 19B can be independently adjusted by adjusting the lengths of the inductors L1 and L2.

For example, when desiring to move the position of the attenuation pole to a low frequency side and adjust the isolation level in the specified frequency band in the second filter 19B while suppressing change of the position of the attenuation pole and the isolation level in the specified frequency band of the first filter 19A as much as possible, the adjustment is possible by making the inductance of the first inductor L1 larger and making the inductance of the second inductor L2 smaller. Note that, the same adjustment is also possible by inserting an inductor between the third ground port G3 of the second filter 19B and the ground terminal 55. However, the attenuation characteristic of the second filter 19B is degraded, therefore this is not preferred. Contrary to this, according to the configuration of the present disclosure, the attenuation characteristic of the second filter 19B can be maintained.

Such a characteristic was for example confirmed in the same way even in a case where the route from the ground port GL of the first filter 19A to the ground terminal 55 was separated from the ground wiring 57 and a case where either of the ground ports G31 and G32 or ground ports 32 and 33 of the second filter 19B were not electrically connected to the ground wiring 57.

Further, the same characteristic was confirmed even in a case where the second inductor L2 was electrically connected to the ground wiring 57 instead of the first inductor L1. However, the trend of change of characteristic became inverse to those shown in FIG. 13B, FIG. 13D, and FIG. 13F. Specifically, for example, when the frequency band in FIG. 13F is focused on, in contrast to the isolation being improved if the first inductor L1 was made longer at the time when the first inductor L1 was connected to the ground wiring 57, the isolation was improved if the second inductor L2 was made longer at the time when the second inductor L2 was connected to the ground wiring 57.

In this way, by selecting the inductor to be connected to the ground wiring 57 from the first inductor L1 and the second inductor L2 according to the desired characteristics, the accuracy and degree of freedom of the characteristic control can be further raised.

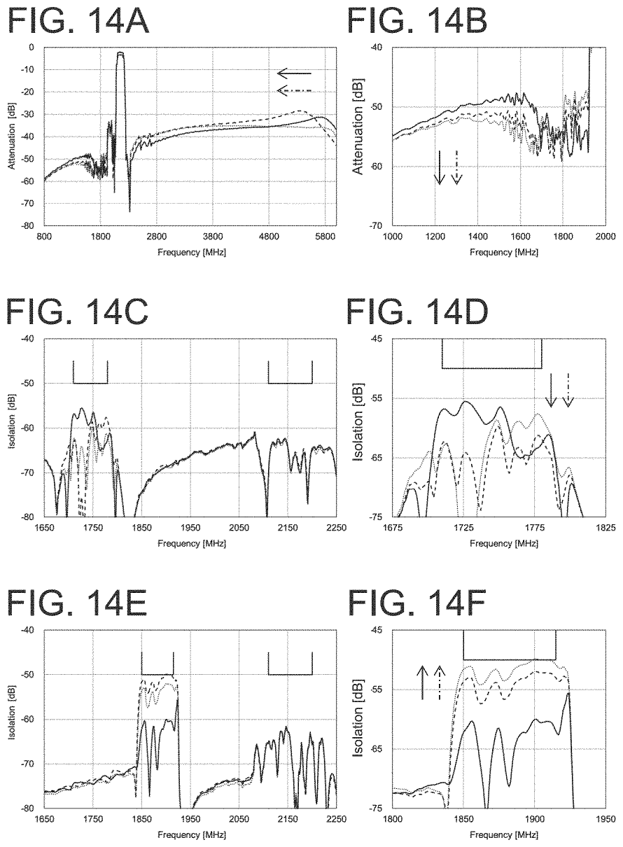

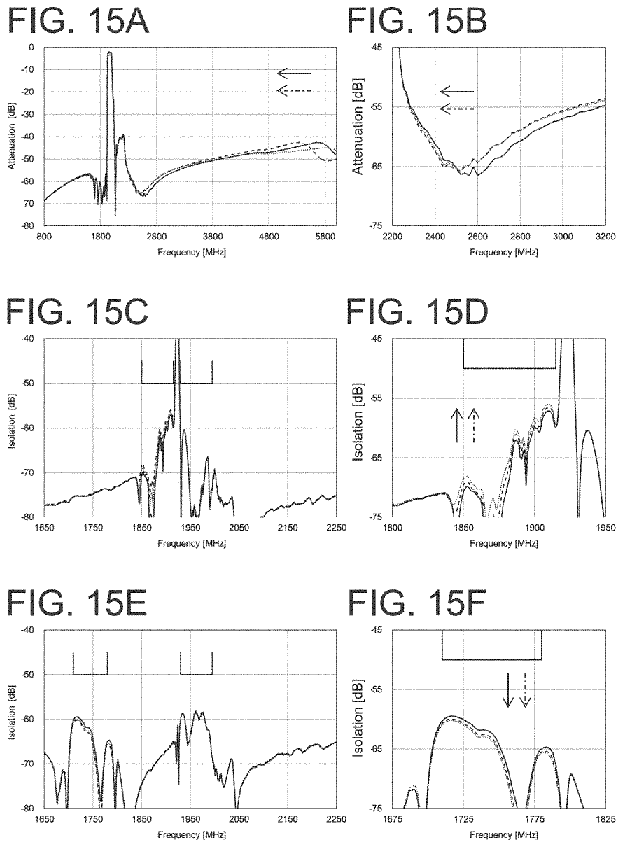

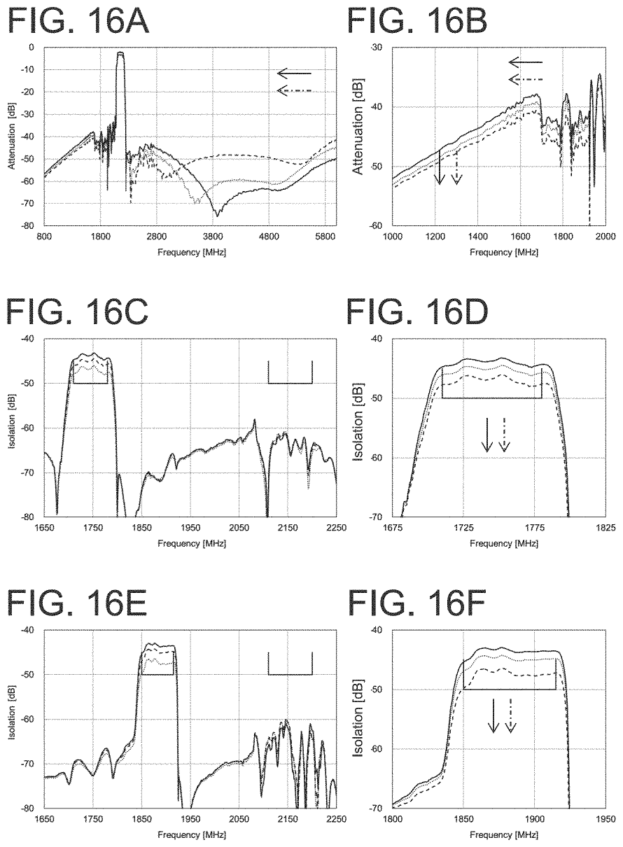

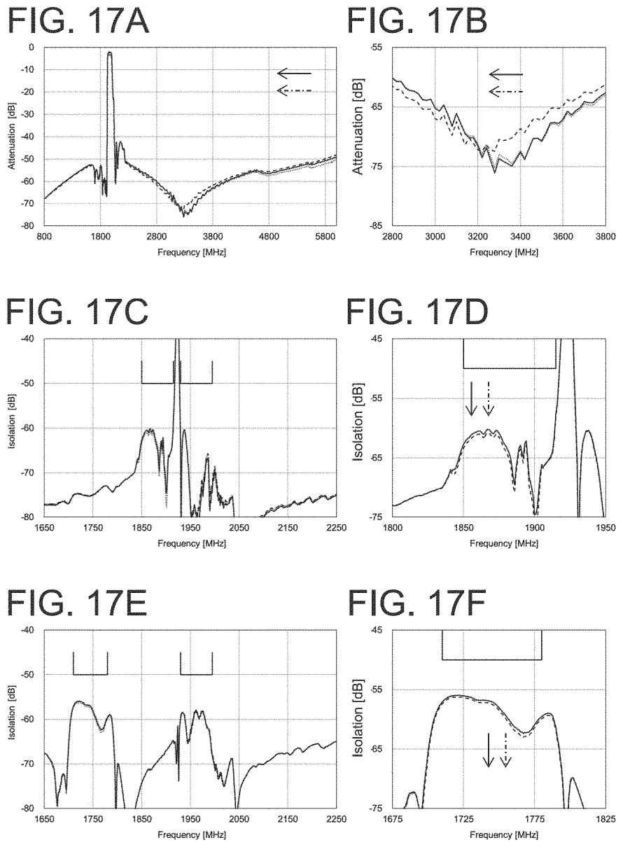

Note that, the transmission characteristics were simulated for a case where both of the first inductor L1 and the second inductor L2 were connected to the ground wiring 57 as Comparative Example 1. In the same way, the transmission characteristics and isolation characteristics were simulated for a case where the ground wiring 57 was not provided and where the first to third ground ports G1 to G3 were individually connected to the ground terminal 55 as Comparative Example 2. FIG. 14 and FIG. 15 show graphs of the transmission characteristics in Comparative Example 1 corresponding to FIG. 12 and FIG. 13, and FIG. 16 and FIG. 17 show the graphs of the transmission characteristics in Comparative Example 2 corresponding to FIG. 12 and FIG. 13.

As apparent also from the graphs, in Comparative Examples 1 and 2, in any of the filters 19A and 19B, the trend of change of characteristic when making the first inductor L1 longer and the trend of change of characteristic when making the second inductor L2 longer are the same. It was confirmed that the characteristics could not be individually adjusted.

From the above, when either of the first ground port or second ground port in the first filter 19A is electrically connected with the third ground port in the second filter 19B, the attenuation poles and isolation characteristics of the two filters 19A and 19B can be individually controlled by adjusting the magnitudes of the inductors connected to the first ground port and second ground port in the first filter. Due to this, the filter device 5 which can easily control the impedance characteristics can be provided.

(Configuration of DMS Filter)

FIG. 18 is a schematic plan view showing the configuration of the principal parts in the DMS filter 45.

The DMS filter 45 is for example configured by a SAW resonator utilizing a SAW. More specifically, the resonator 27 for example includes a piezoelectric substrate 31 and an IDT electrode 33 provided on the upper surface of the piezoelectric substrate 31.

Here, in the longitudinally coupled type filter 29, a plurality of resonators 27 are arranged along the direction of propagation of the SAW. Specifically, a plurality of (three in this example) IDT electrodes 33 are arranged in the direction of propagation of the SAW.

The IDT electrode 33 includes a pair of comb-shaped electrodes 37. Further, among the plurality of IDT electrodes 33 arranged in the direction of propagation of the SAW, the signal is input to the IDT electrode 33 connected to the port P1 and is propagated to the neighboring IDT electrode 33, then the signal is output from the other IDT electrode 33 to the port P2. Here, the other comb-shaped electrode 37b which intermeshes with one comb-shaped electrode 37a connected with the port P1 to which the signal is input is connected to the ground port G2 on the input and/or output port 25 side. The comb-shaped electrode 37b intermeshing with the comb-shaped electrode 37a connected with the port P2 from which the signal is output is connected to the ground port G1 on the antenna terminal 23 side.

Note that, in the example explained above, the case where the resonator 27 was configured as a surface acoustic wave resonator was explained. However, the resonator is not limited to this. For example, a film bulk acoustic resonator (FBAR) or acoustic boundary wave resonator etc. can be used as well.

(Modification 3: Structure)

In the example explained above, the case where a flat multilayer substrate obtained by stacking a plurality of dielectric layers 12 was used as the structure 11 was exemplified. However, the structure is not limited to this.

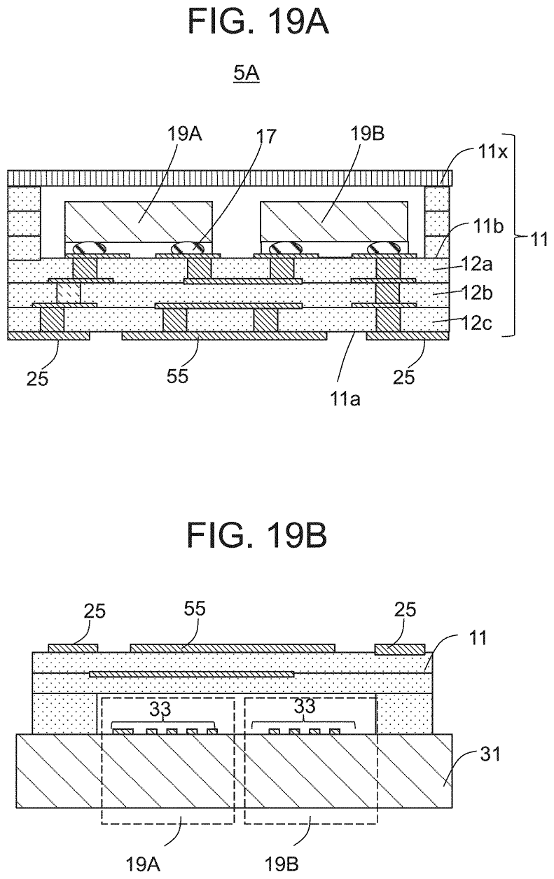

For example, as shown in FIG. 19A, the structure 11 may have a recessed part on the second surface side 11b, and the filters 19 may be arranged in that recessed part. Further, a cap lix closing the opening of the recessed part may be provided to seal the filters 19 as well.

Further, as shown in FIG. 19B, the piezoelectric substrate 31 may be shared by the first filter 19A and second filter 19B and a cap-shaped structure 11 may be provided arranged on the upper surface of the piezoelectric substrate 31. In that case, for example, the wirings may penetrate through the structure 11 from the upper surface side of the piezoelectric substrate 31 or may be electrically led out to the first surface 11a side of the structure 11 along the side surface of the structure. Note that, when use is made of such a cap-shaped structure 11, the first and second inductors L1 and L2 and the ground wiring 57 and the like may be arranged inside the cap-shaped structure 11 as well.

(Modification 4: Filter)

The number of filters and the configurations of the filters excluding the first filter are not particularly limited. In the example explained above, however, the first filter 19A and second filter 19B may be provided with longitudinally coupled type filters, while the third filter 19C and fourth filter 19D may be configured by only ladder type filters. Here, compared with the resonator configuring the ladder type filter, the resonator configuring the longitudinally coupled type filter has a smaller capacity value of one resonator. From this fact, the influence by the first and second inductors L1 and L2 becomes larger in the first filter 19A and the second filter 19B, therefore the attenuation poles of the filters and the like can be individually controlled. On the other hand, the other filters 19C and 19D are larger in the capacities of the resonators, therefore the influence by the first and second inductors L1 and L2 becomes smaller. As a result, even in a case where three or more filters are commonly connected, the characteristics of only the two filters can be individually controlled.

Note that, for the reason explained above, the second filter 19B may be provided with a DMS filter as well. However, the second filter is not limited to this. For example, use may be made of a ladder type resonator filter as well.

Further, the first filter 19A may be made higher in passing band compared with the second filter 19B as well. This is because, in this case, by providing an inductor at the side of the filter having a higher passing band, even if the impedance on the high frequency side changes due to insertion of the inductor, the influence upon the other filter can be reduced.

Note that, in the two filters 19 adjusted in the positions of the attenuation poles by using the ground wiring 57, it is confirmed that the adjustment of impedance is possible in the same way in the case where the individual inductor 53 is connected to any of the filters 19 and the case where it is not connected to any of the filters 19

The art according to the present disclosure is not limited to the above embodiment and may be worked in various ways.

For example, the resonator configuring the filter is not limited to one using the IDT electrode as the excitation electrode and may be a film bulk acoustic resonator as well. The acoustic wave is not limited to a SAW and may be for example a bulk wave or acoustic boundary wave (however, it may be grasped as one type of SAW) as well.

Further, the number of the filters included in the filter device need only be two or more and is not limited to four. For example, the number may be two in a duplexer, six in a hexaplexer, or the like.

Further, in the example shown in FIG. 2, the case where the piezoelectric substrate was shared by the filters was explained. However, the art is not limited to this. An individual chip may be used for each filter, or a substrate may be shared by part of the filters and substrates may be individually provided for the other filters.

Further, as explained before, the effect according to the individual inductor and the effect according to the ground wiring are independent, therefore the following concepts can be extracted.

[Concept 1]

A filter device including:

a structure which includes a first surface and a second surface on the opposite side to this, includes an antenna terminal, a first terminal, a second terminal, and a ground terminal on the first surface and in which the terminals are electrically led out to the second surface side,

a first filter which is located on the second surface side in the structure, is electrically connected between the antenna terminal and the first terminal and includes a longitudinally coupled filter, and

a second filter which is located on the second surface side in the structure and is electrically connected between the antenna terminal and the second terminal, wherein

the first filter includes a first ground port on the antenna terminal side in the longitudinally coupled filter and a second ground port on the first terminal side in the longitudinally coupled filter which are electrically connected with the ground terminal,

the second filter includes a third ground port which is electrically connected with the ground terminal, and

the structure, between the first surface and the second surface, includes
a first inductor which is connected in series between the first ground port and the ground terminal,
a second inductor which is connected in series between the second ground port and the ground terminal, and
a ground wiring which electrically connects either of the ground terminal side of the first inductor and the ground terminal side of the second inductor with the third ground port and is not connected to the other.

### [Concept 2]

The filter device according to Concept 1, wherein the second filter includes a second longitudinally coupled filter.

### [Concept 3]

The filter device according to Concept 1 or 2, wherein the first filter includes a ladder type filter which is serially connected on a side closer to the antenna terminal than the longitudinally coupled filter.

### [Concept 4]

The filter device according to any one of Concepts 1 to 3, wherein a passing band of the first filter is located on a higher frequency side compared with a passing band of the second filter.

### [Concept 5]

The filter device according to any of Concepts 1 to 4, wherein the structure is a multilayer substrate in which a plurality of dielectric layers are stacked and wherein the ground wiring is configured by a conductor pattern among the plurality of dielectric layers.

### REFERENCE SIGNS LIST

1 . . . communication apparatus, 5 . . . filter device, 19A . . . first filter, 23 . . . antenna terminal, 24w, 24v, 24x . . . branch points, 51 . . . common inductor, 53 . . . individual inductor, and B1 to B4 . . . passing bands.

1. A filter device comprising:
an antenna terminal,
two or more filters which are connected to the antenna terminal, are branched from each other when viewed from the antenna terminal, and are different in passing bands from each other,
an individual inductor which is connected in series between a first filter among the two or more filters and a branch point from which the first filter is branched to be independent from other filters among the two or more filters when viewed from the antenna terminal, and
a common inductor which is located between a position between the antenna terminal and the branch point and a reference potential and is commonly connected in parallel with respect to the two or more filters, wherein
the first filter is higher in frequency of passing band compared with the other filters among the two or more filters,
the two or more filters include a second filter, and,
a susceptance when viewing the second filter from the antenna terminal side at the frequency of a passing band of the second filter is larger than a susceptance when viewing the first filter from the antenna terminal side at a frequency of a passing band of the first filter.

2. The filter device according to claim 1, wherein the individual inductor has a smaller inductance than that of the common inductor.

3. The filter device according to claim 1, wherein each of the two or more filters includes at least one surface acoustic wave resonator.

4. The filter device according to claim 3, wherein a combined capacity of a surface acoustic wave resonator located closest to the antenna terminal side among the surface acoustic wave resonators configuring the first filter is larger than a combined capacity of a surface acoustic wave resonator located closest to the antenna terminal side among the surface acoustic wave resonators configuring the second filter.

5. The filter device according to claim 1, wherein the two or more filters include a third filter and a fourth filter.

6. The filter device according to claim 5, wherein when the passing bands of the two or more filters are arranged in order of frequencies, an interval between the passing band of the first filter and a passing band neighboring to the first filter is broader than any interval between any other neighboring passing bands.

7. The filter device according to claim 5, wherein, at the frequency of the passing band of the first filter, a susceptance when viewing the third filter side from the antenna terminal is larger than a susceptance when viewing the first filter side from the antenna terminal.

8. The filter device according to claim 5, wherein the first filter is a reception filter, and the second filter and the third filter are transmission filters.

9. The filter device according to claim 1, wherein:
the two or more filters includes a first acoustic wave filter and a second acoustic wave filter,
the filter device comprises
structure which comprises a first surface and a second surface on the opposite side to the first surface, comprises an antenna terminal, a first terminal, a second terminal, and a ground terminal on the first surface and in which the terminals are electrically led out to the second surface side,
a first acoustic wave filter which is located on the second surface side in the structure, is electrically connected between the antenna terminal and the first terminal and includes a longitudinally coupled filter, and
a second acoustic wave filter which is located on the second surface side in the structure and is electrically connected between the antenna terminal and the second terminal,
the first acoustic wave filter comprises a first ground port on the antenna terminal side of the longitudinally coupled filter and a second ground port on the first terminal side of the longitudinally coupled filter which are electrically connected to the ground terminal,
the second acoustic wave filter comprises a third ground port which is electrically connected to the ground terminal, and
the structure, between the first surface and the second surface, comprises
a first inductor which is connected in series between the first ground port and the ground terminal,
a second inductor which is connected in series between the second ground port and the ground terminal, and
a ground wiring which electrically connects one of the ground terminal side of the first inductor and the ground terminal side of the second inductor with the third ground port and is not connected to the other of the ground terminal side of the first inductor and the ground terminal side of the second inductor.

10. A communication apparatus comprising:
a filter device according to claim 1,
an antenna which is connected to the antenna terminal side of the filter device, and
an RF-IC which is connected to another side of the filter device which is opposite to the antenna terminal.
